(19) United States
(12) Patent Application Publication
(10) Pub. No.: US 2007/0252634 A1
(43) Pub. Date: Nov. 1, 2007

(54) Signal switching circuit involving no signal discontinuation

(75) Inventor: Akihide Adachi, Fukushima-ken (JP)

Correspondence Address: BEYER WEAVER LLP, P.O. BOX 70250, OAKLAND, CA, 94612-0250, US

(73) Assignee: ALPS ELECTRIC CO., LTD.

(21) Appl. No.: 11/788,121

(22) Filed: Apr. 19, 2007

(30) Foreign Application Priority Data
Apr. 27, 2006 (JP) 2006-123537

(51) Int. Cl. H03K 17/00

(52) U.S. Cl. 327/365

(57) ABSTRACT

A signal switching circuit includes an input terminal to which a signal is input, an output terminal from which a signal is output, a first electronic circuit and a second electronic circuit which are alternately connected between the input terminal and the output terminal, and switching elements for alternately connecting the first electronic circuit and the second electronic circuit between the input terminal and the output terminal through a selection. A signal alternative path for connecting between the input terminal and the output terminal at all times is provided. Even when the switching elements are in an open state, the signal that is input to the input terminal is output to the output terminal via the signal alternative path.

### CLAIM OF PRIORITY

This application claims benefit of the Japanese Patent Application No. 2006-123537 filed on Apr. 27, 2006, which is hereby incorporated by reference.

### BACKGROUND OF THE INVENTION

1. Field of the Invention

The present invention relates to a signal switching circuit, in particular, a signal switching circuit for propagating a signal while switching a state of the signal.

2. Description of the Related Art

FIG. 3 symbolically illustrates an example of a conventional signal switching circuit of this type. In this signal switching circuit, a signal that is input to an input terminal 11 is propagated to an output terminal 15 via one of a through circuit 13 and an attenuation circuit 14 through a switching connection with use of switching elements 12a and 12b. Then, the single is output to an electronic circuit in a later stage (now illustrated in the drawing). As the switching elements 12a and 12b, a relay, an FET switch, a diode switch, and the like are used, which are adapted to perform a switching in response to an external control voltage.

Circuit examples which use such a signal switching circuit include an antenna switching circuit in a digital diversity reception device (refer to Japanese Unexamined Patent Application Publication No. 2004-186911) and a switching circuit for inserting an input level change attenuation circuit to a signal line (refer to Japanese Unexamined Patent Application Publication No. 06-132844).

However, the following inconvenience occurs in the conventional signal switching circuit. That is, in response to a switching of switching elements, although even for an instant moment, irrespective of a digital signal or an analog signal, such a time is generated that the signal is not connected to any path, thus causing a discontinuation of the signal.

In particular, in a high speed digital communications network, the discontinuation of the signal should be avoided even the discontinuation only takes a moment.

Also, in a high frequency circuit, in particular, in a digital encoding device, if an input signal is discontinued for even a moment, such an inconvenience occurs that an error is generated due to missing data in a circuit in a later stage.

To be more specific, as described in the section where problems are mentioned in Japanese Unexamined Patent Application Publication No. 2004-186911, a signal is discontinued at a moment of an antenna switching in the digital diversity reception device or the like, a synchronization of digital signals cannot be attained in a demodulation circuit, and there is a problem that a reception failure is caused.

In addition, in the switching circuit for inserting the input level change attenuation circuit illustrated in FIG. 2 of Japanese Unexamined Patent Application Publication No. 06-132844, a signal is discontinued at a moment of a connection switching. If a digital signal processing circuit is connected in a later stage, the above-described problem is generated.

### SUMMARY OF THE INVENTION

The present invention has been made in view of the above and therefore provides a signal switching circuit which is capable of propagating a signal with certainty at all times involving no signal discontinuation even at a moment of a connection switching.

A signal switching circuit according to an aspect of the present invention includes: an input terminal to which a signal is input; an output terminal from which a signal is output; a first electronic circuit and a second electronic circuit which are alternately connected between the input terminal and the output terminal; and switching elements for alternately connecting the first electronic circuit and the second electronic circuit between the input terminal and the output terminal through a selection, in which a signal alternative path for connecting between the input terminal and the output terminal at all times is provided, and even when the switching elements are in an open state, the signal that is input to the input terminal is output to the output terminal via the signal alternative path.

In the signal switching circuit according to this aspect of the present invention, as the signal alternative path connects between the input terminal and the output terminal at all times, even when the switching elements are in the open state, the signal that is input to the input terminal is output to the output terminal via the signal alternative path. Thus, the signal is not discontinued even at a moment of the connection switching, and it is possible to propagate the signal with certainty at all times.

Also, according to of another aspect of the present invention, in the above-described signal switching circuit, one of the first electronic circuit and the second electronic circuit is a through circuit, and the other is a circuit that constitute a part of a resistance attenuation circuit; the signal alternative path has a resistance; and when the circuit that constitute the part of the resistance attenuation circuit is selected, a resistance of the signal alternative path constitutes the other part of the resistance attenuation circuit.

In the signal switching circuit according to this aspect of the present invention, as one of the first electronic circuit and the second electronic circuit is connected through a selection with the switching elements, it is possible to connect the through circuit and the resistance attenuation circuit through a selection. At the same time, with use of the signal alternative path, even at the moment of the connection switching, the signal is not discontinued. Thus, the signal can be propagated with certainty at all times. Furthermore, the signal alternative path constitutes the other part for completing the resistance attenuation circuit, whereby it is possible to achieve a simplification and a miniaturization of the configuration of the signal switching circuit itself.

Moreover, according to of another aspect of the present invention, in the above-described signal switching circuit, the resistance attenuation circuit is a p-type resistance attenuation circuit in which the resistance of the signal alternative path is connected in parallel to a signal path.

In the signal switching circuit according to this aspect of the present invention, when the resistance attenuation circuit is connected through a selection by the switching elements, the resistance of the signal alternative path connected in parallel to the signal path is a constitutes the p-type resistance attenuation circuit as the attenuation circuit. Thus, the signal can be output while being subjected to a reliable attenuation effect.

Furthermore, according to of another aspect of the present invention, in the above-described signal switching circuit, the signal is a digital signal.

In the signal switching circuit according to this aspect of the present invention, even in the case of the digital signal which imparts a large influence on a signal process in a later stage if the signal propagation is discontinued, the signal is not discontinued at a moment of the connection switching between the first electronic circuit and the second electronic circuit. As a result, it is possible to propagate the signal with certainty at all times.

As described above, according to the signal switching circuit of the present invention, the signal is not discontinued even at the moment of the connection switching, whereby an excellent effect can be attained in that it is possible to propagate the signal with certainty at all times.

### BRIEF DESCRIPTION OF THE DRAWINGS

FIG. 1 is a circuit diagram illustrating a signal switching circuit according to an embodiment of the present invention;

FIG. 2 is a circuit diagram illustrating a situation where a connection state of the signal switching circuit of FIG. 1 is switched; and

FIG. 3 is a circuit diagram illustrating an example of a conventional signal switching circuit.

### DESCRIPTION OF THE PREFERRED EMBODIMENTS

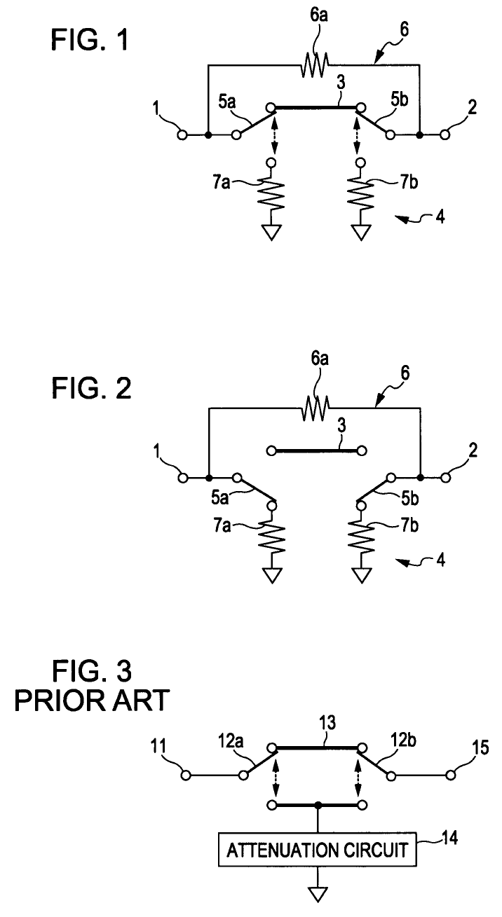

Hereinafter, a signal switching circuit according to an embodiment of the present invention will be described with reference to FIGS. 1 and 2.

FIGS. 1 and 2 illustrate the signal switching circuit according to the embodiment, showing a situation where a connection state is switched.

As illustrated in FIGS. 1 and 2, the signal switching circuit according to the embodiment includes an input terminal 1 to which a signal is input, an output terminal from which a signal is output. A first electronic circuit 3 and a second electronic circuit 4 are provided to be alternately connected between the input and output terminals 1 and 2. In addition, the switching elements 5a and 5b for alternately connecting one of the electronic circuits 3 and 4 between the input and output terminals 1 and 2 through a selection. For the switching elements 5a and 5b, a relay, an FET switch, a diode switch, and the like may be used. The switching elements 5a and 5b are configured to be switched in response to an external control voltage. Furthermore, a signal alternative path 6 for connecting the input and output terminals 1 and 2 therebetween at all times is provided between those terminals. Also, the electronic circuit 3 as one of the electronic circuits 3 and 4 is a through circuit formed in such a manner that no change is imparted on the signal input to the input terminal 1 and the signal is propagated as it is to the output terminal 2. The electronic circuit 4 as the other electronic circuit is provided with two resistors 7a and 7b which are respectively connected to the input and output terminals 1 and 2 when the switching elements 5a and 5b are connected thereto. The signal alternative path 6 has a resistor 6a that is connected in parallel to a signal path connecting between the input and output terminals 1 and 2. Then, the resistors 7a and 7b of the electronic circuit 4 and the resistor 6a of the signal alternative path 6 constitute a part of a circuit for completing a p-type resistance attenuation circuit which is an embodiment of a resistance attenuation circuit, when both the switching elements 5a and 5b are connected to the electronic circuit 4 side.

Next, operations of this embodiment will be described with reference to FIGS. 1 and 2.

FIG. 1 illustrates a state where both the switching elements 5a and 5b are connected to the through circuit of the first electronic circuit 3. In this connection state, no change is imparted on the signal that is input to the input terminal 1. The signal passes the through circuit as it is and is propagated to the output terminal 2. Then, the signal is output to an electronic circuit or the like (not illustrated in the drawing) in a later state.

From this connection state of FIG. 1, an external control voltage is used to switch the connection of the switching elements 5a and 5b from the first electronic circuit 3 to the second electronic circuit 4. This switching time is as short as only approximately several nano seconds to several micro second.

According to the signal switching circuit of this embodiment, the signal alternative path 6 is connected between the input and output terminals 1 and 2 at all times. Thus, even at the switching time when both the switching elements 5a and 5b are put into the open state for about several nano seconds to several micro second, the signal that is input to the input terminal 1 is output to the output terminal 2 via the signal alternative path 6. Therefore, the signal is not discontinued even at the moment of the connection switching, whereby it is possible to propagate the signal with certainty at all times. Also, according to the signal switching circuit of this embodiment, even in the case of a digital signal which imparts a large influence on a signal process in a later stage if the propagation of a signal that should be propagated is discontinued, even at the moment when the connection of the first and second electronic circuits 3 and 4 is switched by the switching elements 5a and 5b, the signal is not discontinued at all and the signal can be propagated with certainty at all times.

Furthermore, when the second electronic circuit 4 is connected through the selection by the switching elements 5a and 5b, the resistor 6a of the signal alternative path 6 connected in parallel to the signal path and the resistors 7a and 7b of the second electronic circuit 4 constitute the p-type resistance attenuation circuit as the resistance attenuation circuit. As a result, the signal can be propagated and output to the output terminal 2 while being subjected to a reliable attenuation effect.

Furthermore, according to the signal switching circuit of this embodiment, with the provision of the resistor 6a in the signal alternative path 6, the resistance attenuation circuit can be completed through the use of combination options of the resistors 7a and 7b of the first and second electronic circuits 3 and 4, whereby it is possible to achieve a simplification and a miniaturization of the configuration of the signal switching circuit itself.

It should be noted that the present invention is not limited to the above-described embodiment and can be modified in various modes as necessary.

What is claimed is:

1. A signal switching circuit, comprising: an input terminal to which a signal is input; an output terminal from which a signal is output; a first electronic circuit and a second electronic circuit which are alternately connected between the input terminal and the output terminal; and switching elements for alternately connecting the first electronic circuit and the second electronic circuit between the input terminal and the output terminal through a selection, wherein:
a signal alternative path for connecting between the input terminal and the output terminal at all times is provided; and
even when the switching elements are in an open state, the signal that is input to the input terminal is output to the output terminal via the signal alternative path.

2. The signal switching circuit according to claim 1, wherein:
one of the first electronic circuit and the second electronic circuit is a through circuit, and the other is a circuit that constitute a part of a resistance attenuation circuit;
the signal alternative path has a resistance; and
when the circuit that constitute the part of the resistance attenuation circuit is selected, a resistance of the signal alternative path constitutes the other part of the resistance attenuation circuit.

3. The signal switching circuit according to claim 2, wherein the resistance attenuation circuit is a p-type resistance attenuation circuit in which the resistance of the signal alternative path is connected in parallel to a signal path.

4. The signal switching circuit according to claim 1, wherein the signal is a digital signal.
